(19) United States
(12) Patent Application Publication
(10) Pub. No.: US 2013/0189822 A1
(43) Pub. Date: Jul. 25, 2013

(54) METHODS OF FABRICATING INTEGRATED CIRCUITS WITH THE ELIMINATION OF VOIDS IN INTERLAYER DIELECTICS

(71) Applicants: Kai Frohberg, Niederau (DE); Torsten Huisinga, Dresden (DE); Katrin Reiche, Goltzscha (DE)

(72) Inventors: Kai Frohberg, Niederau (DE); Torsten Huisinga, Dresden (DE); Katrin Reiche, Goltzscha (DE)

(73) Assignee: GLOBALFOUNDRIES INC., Grand Cayman (KY)

(21) Appl. No.: 13/357,285

(22) Filed: Jan. 24, 2012

(51) Int. Cl. H01L 21/336

(52) U.S. Cl. 438/303; 438/299; 257/E21.409

(57) ABSTRACT

Methods are provided for fabricating integrated circuits that include forming first and second spaced apart gate structures overlying a semiconductor substrate, and forming first and second spaced apart source/drain regions in the semiconductor substrate between the gate structures. A first layer of insulating material is deposited overlying the gate structures and the source/drain regions by a process of atomic layer deposition, and a second layer of insulating material is deposited overlying the first layer by a process of chemical vapor deposition. First and second openings are etched through the second layer and the first layer to expose portions of the source/drain regions. The first and second openings are filled with conductive material to form first and second spaced apart contacts, electrically isolated from each other, in electrical contact with the first and second source/drain regions.

### TECHNICAL FIELD

The present invention generally relates to methods for fabricating integrated circuits and more particularly relates to methods for fabricating integrated circuits that eliminate voids in interlayer dielectrics.

### BACKGROUND

The trend in semiconductor integrated circuit (IC) design and fabrication is to increase the density and to include more and more devices on each circuit. This trend requires the feature size, which includes both the minimum device size and the minimum spacing between devices, to be reduced. The increase in integration density of semiconductor ICs provides both an economic and performance benefit, but does this at the expense of increased manufacturing difficulty.

As an example of the increased manufacturing difficulty, consider that as feature size is reduced, the spacing between transistor gate structures of a field effect transistor (FET) IC is dramatically reduced and it becomes difficult to deposit a void-free interlayer dielectric (ILD) overlying the gate structures. Voids in the ILD can lead to shorts between active area contacts (for example, contacts to source/drain regions) during subsequent processing because metal forming the contacts migrates through the voids and causes electrical shorts. Such electrical shorts lead to device failure and loss of manufacturing yield. Standard chemical vapor deposition (CVD) processes are unable to reliably fill the gaps between closely spaced structures such as FET gate structures in a void-free manner. Although atomic layer deposition (ALD) is capable of producing void-free dielectric layers, ALD is slow and expensive and thus is not useful as a manufacturing tool for depositing relatively thick ILD.

Accordingly, it is desirable to provide methods for fabricating integrated circuits that include providing void-free dielectric layers. In addition, it is desirable to provide methods for fabricating ICs that are capable of high volume manufacturing. Furthermore, other desirable features and characteristics of the present invention will become apparent from the subsequent detailed description and the appended claims, taken in conjunction with the accompanying drawings and the foregoing technical field and background.

### BRIEF SUMMARY

Methods are provided for fabricating integrated circuits that avoid gaps in interlayer dielectrics (ILDs). In accordance with one embodiment the method includes forming first and second spaced apart gate structures overlying a semiconductor substrate, and forming first and second spaced apart source/drain regions in the semiconductor substrate between the gate structures. A first layer of insulating material is deposited overlying the gate structures and the source/drain regions by a process of atomic layer deposition, and a second layer of insulating material is deposited overlying the first layer by a process of chemical vapor deposition. First and second openings are etched through the second layer and the first layer to expose portions of the source/drain regions. The first and second openings are filled with conductive material to form first and second spaced apart contacts, electrically isolated from each other, in electrical contact with the first and second source/drain regions.

In accordance with another embodiment the method includes forming first and second spaced apart structures overlying a semiconductor substrate and depositing a first layer of insulating material overlying the structures by a process of atomic layer deposition. A second layer of insulating material is deposited overlying the first layer, and first and second spaced apart electrically conductive contacts are formed extending through the second layer and the first layer to the semiconductor substrate between the first and second structures.

In accordance with yet another embodiment the method includes forming first and second spaced apart gate electrode structures overlying a semiconductor substrate. Sidewall spacers are formed on the first and second gate electrode structures and first and second spaced apart source/drain regions are formed by ion implantation between the first and second gate electrode structures. Metal silicide contacts are formed on the first and second source/drain regions and a layer of stress inducing dielectric material is deposited overlying the first and second gate electrode structures. A first layer of oxide is deposited overlying the first and second gate electrode structures and first and second source/drain regions by a process of atomic layer deposition. A second layer of oxide is deposited overlying the first layer by a process of chemical vapor deposition, and a third layer of oxide is deposited overlying the second layer by a process of plasma enhanced chemical vapor deposition. The third layer is planarized and first and second spaced apart opening are etched through the third layer, second layer, and first layer to expose portions of the metal silicide contacts. The first and second openings are filled with conductive material to form first and second spaced apart contacts to the first and second source/drain regions.

### BRIEF DESCRIPTION OF THE DRAWINGS

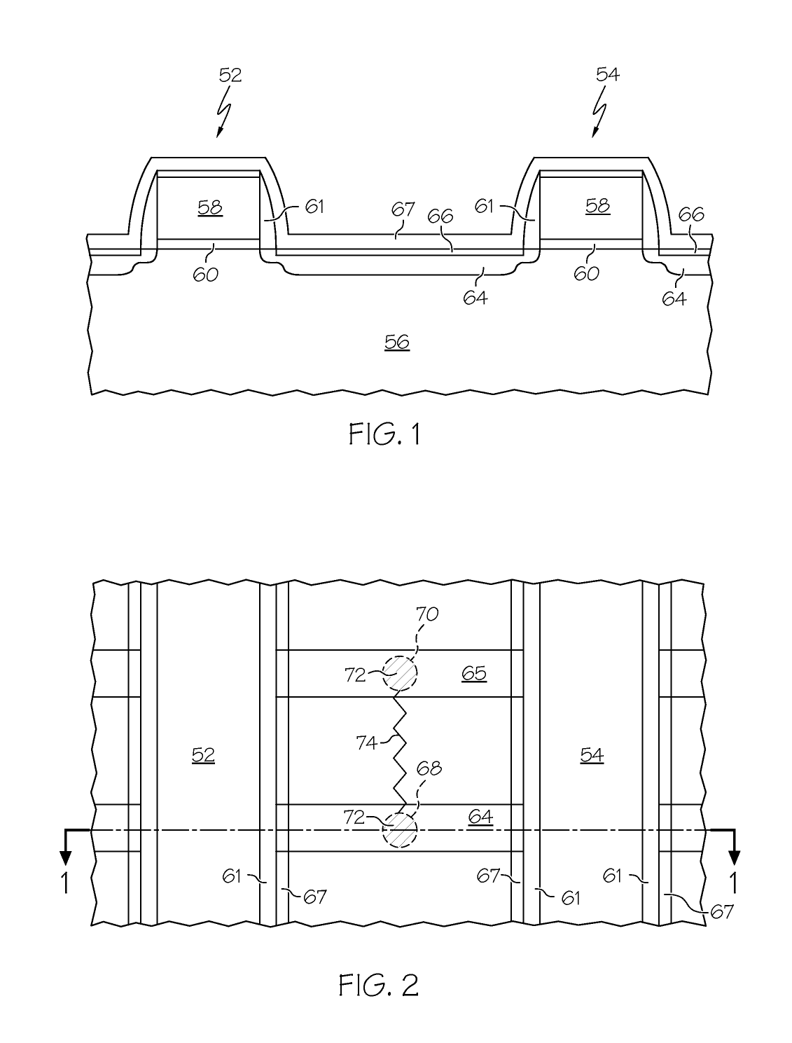

The present invention will hereinafter be described in conjunction with the following drawing figures, wherein like numerals denote like elements, and wherein FIGS. 1-6 illustrate method steps for fabricating an integrated circuit in accordance with various embodiments. FIGS. 1, 3, 4, and 5 are cross-sectional views, and FIGS. 2 and 6 are top views.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Methods are provided for fabricating semiconductor integrated circuits (ICs) that include void-free dielectric layers and that can be manufactured in a high volume, timely manufacturing line. FIGS. 1-6 schematically illustrate, in simplified views, process steps for the fabrication of an IC 50 in accordance with various exemplary embodiments. The FIGURES illustrate only a portion of an IC, but those of skill in the art will understand how the concepts illustrated can be applied to a total IC. Various steps in the manufacture of ICs are well known to those of skill in the art and so, in the interest of brevity, many conventional steps will only be mentioned briefly herein or will be omitted entirely without providing the well known process details. The embodiments illustrated all relate to the fabrication of field effect transistor (FET) ICs, but the illustrated teachings are, of course, applicable to a wide variety of devices, and the claims are to be so interpreted.

Methods for fabricating an IC 50, in accordance with one embodiment, begin as illustrated in cross-sectional view in FIG. 1 with conventional fabrication steps. A plurality of spaced apart gate structures 52, 54 (only two of which are illustrated) are formed overlying a semiconductor substrate 56. The semiconductor substrate can be silicon, silicon admixed with germanium or other elements, or other semiconducting materials commonly used in fabricating semiconductor devices. Gate structures 52, 54 include gate electrodes 58 that can be polycrystalline silicon, metals, other conductive materials or layered structures that include two of more of these materials. The gate electrodes are electrically isolated from semiconductor substrate 56 by a gate dielectric 60. The gate dielectric can be, for example, silicon dioxide, a high dielectric constant (high k) insulating material, or other insulating material, either alone or in layered combination. In accordance with one exemplary embodiment the spacing between gate structures is about 100-112 nanometers (nm), the height of the gate structures is about 48-52 nm, and the gate dielectric has a thickness of about 1-10 nm. Sidewall spacers 61 are formed on the edges of the gate structures. Although only one spacer is shown on each sidewall of the gate structures, one or more spacers may be used as needed to assist in the proper spacing and alignment of subsequently formed source/drain regions, metal silicide contacts, and the like. The spacers can be formed of silicon nitride or other insulating material and can have a thickness of about 30 nm. Spaced apart source/drain regions 64, 65 (only source/drain region 64 is seen in this cross-sectional view) are formed in the semiconductor substrate in the space between gate structures 52, 54 and in self alignment with the gate structures, for example by the implantation of conductivity determining ions such as ions of arsenic, phosphorous, or boron. If the semiconductor substrate is primarily silicon, a metal silicide layer 66 is formed in a portion of the surface of the source/drain regions by depositing a silicide-forming metal and heating to cause the metal to react with exposed silicon. The silicide forms only where the metal is in contact with exposed silicon, not on insulator material such as the sidewall spacers, so the metal silicide forms in self alignment with the gate structures. The silicide forming metal can be, for example, nickel or nickel and platinum. In accordance with one embodiment a layer of stress inducing insulating material 67 is deposited overlying the spaced apart gate structures and the spaced apart source/drain regions and metal silicide layer. The stress inducing insulating material, typically a layer of silicon nitride having a thickness of about 20 to about 30 nm, can be deposited as either a compressive layer or a tensile layer depending on whether the FET being formed is a P-channel or an N-channel FET. The stress inducing layer creates a strain in the channel of the FET which increases mobility of majority carriers in the channel.

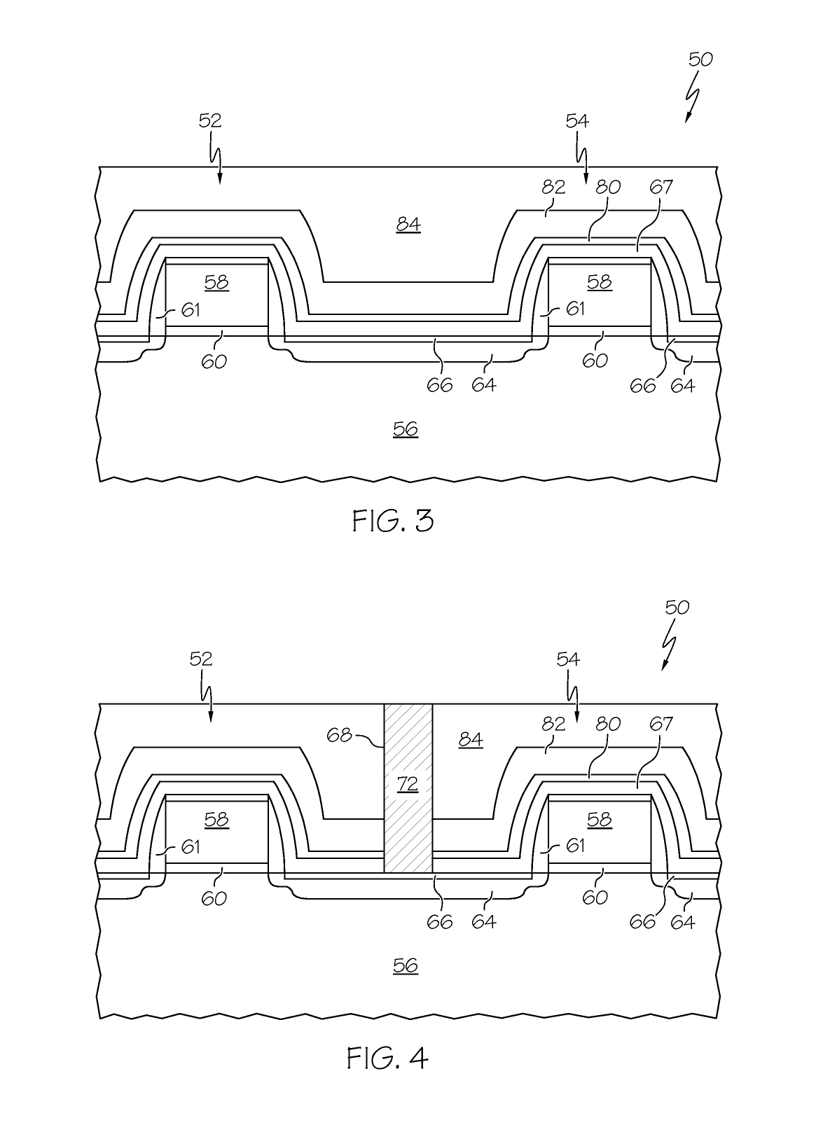

FIG. 2 illustrates IC 50, in a simplified top view. For reference, FIG. 1 (as well as subsequent FIGS. 3 and 4) is a cross-sectional view taken along the line 1-1. After processing IC 50 as illustrated in FIG. 1, an interlayer dielectric (ILD) is deposited overlying the gate structures and the source/drain regions, openings 68, 70 are etched through the dielectric layer, as indicated by the dashed circles, overlying spaced apart source/drain regions, and the openings are filled with a conductive material 72 to facilitate electrical contact to the source/drain regions. The spacing between openings 68, 70 can be as little as 90 nm. In prior art processes the ILD was deposited by a chemical vapor deposition (CVD) process. Because of the narrow spacing between gate structures 52, 54 and the height of the gate structures, resulting in a high aspect ratio valley to be filled, it is difficult to deposit the dielectric layer without voids. Instead, using a CVD process to deposit the ILD layer often resulted in the inclusion of voids in the layer as illustrated by the line 74 extending between opening 68 and opening 70. When openings 68, 70 are filled with conductive material, the conductive material can travel along the void causing a short between the unrelated source/drain regions 64, 65 leading to device failure.

The problems of the prior art process are overcome by embodiments of the present methods, the continuation of which are illustrated in cross-section in FIG. 3. In accordance with one embodiment, after the formation of stress inducing layer 67, if one is used, a thin layer of insulating material 80 such as silicon oxide is deposited by atomic layer deposition (ALD). Preferably the ALD layer of insulating material has a thickness of about 6-10 nm. ALD is a surface controlled layer-by-layer process for the deposition of thin films with atomic layer accuracy. ALD deposits one atomic layer at a time through a reaction cycle of alternative pulsing of precursors and reactants. The insulating layer can be deposited, for example at a temperature of about 300° C. and at a pressure of about 2.7 Torr. A layer thickness of about 6 nm can be deposited in a little more than 5 minutes and about 130 cycles. Each atomic layer formed in the sequential process is a result of saturated surface controlled reactions. Because of the self limiting nature of the ALD process, precise film thickness and conformity can be achieved, even in high aspect ratio valleys. The surface control achieved with ALD results in the deposition of thin, uniform, and void-free films. The deposition of layer 80 by an ALD process thus provides a void-free insulating layer completely covering metal silicide layer 66, source/drain regions 64, 65, and the surface between the source/drain regions. After depositing layer 80, a thick layer of insulating material is deposited overlying layer 80 by a CVD process. Preferably the thick layer is deposited in two steps: first a layer of insulating material 82 is deposited by subatmospheric chemical vapor deposition (SACVD) to a thickness of about 95-105 nm, and then a thicker layer of insulating material 84 is deposited over layer 82 by a process of plasma enhanced chemical vapor deposition (PECVD) to completely fill the valley between spaced apart gate structures 52, 54. In accordance with one embodiment both layer 82 and layer 84 are formed of a silicon oxide deposited from a tetraethyl orthosilicate (TEOS) source. The upper surface of layer 84 is planarized, for example by chemical mechanical planarization (CMP) to achieve the structure illustrated in FIG. 3.

As illustrated in cross-section in FIG. 4, the method in accordance with one embodiment continues by etching contact openings 68, 70 (only contact opening 68 is seen in this cross sectional view) that extend through insulating layers 84, 82, 80, and the layer of stress inducing material 67 to expose a portion of metal silicide layer 66 on source/drain regions 64, 65. Openings 68, 70 are filled with a conductive material 72 to facilitate electrical contact to the source/drain regions. In accordance with one exemplary embodiment the conductive material consists of sequential layers of titanium and titanium nitride followed by tungsten. The conductive material deposited on the planarized surface of insulating layer 84 is removed, for example by CMP. Because of the presence of the void-free ILD layer overlying and between the spaced apart source/drain regions through which openings 68, 70 have been etched, the conductive material in opening 68 is electrically isolated from the conductive material in opening 70.

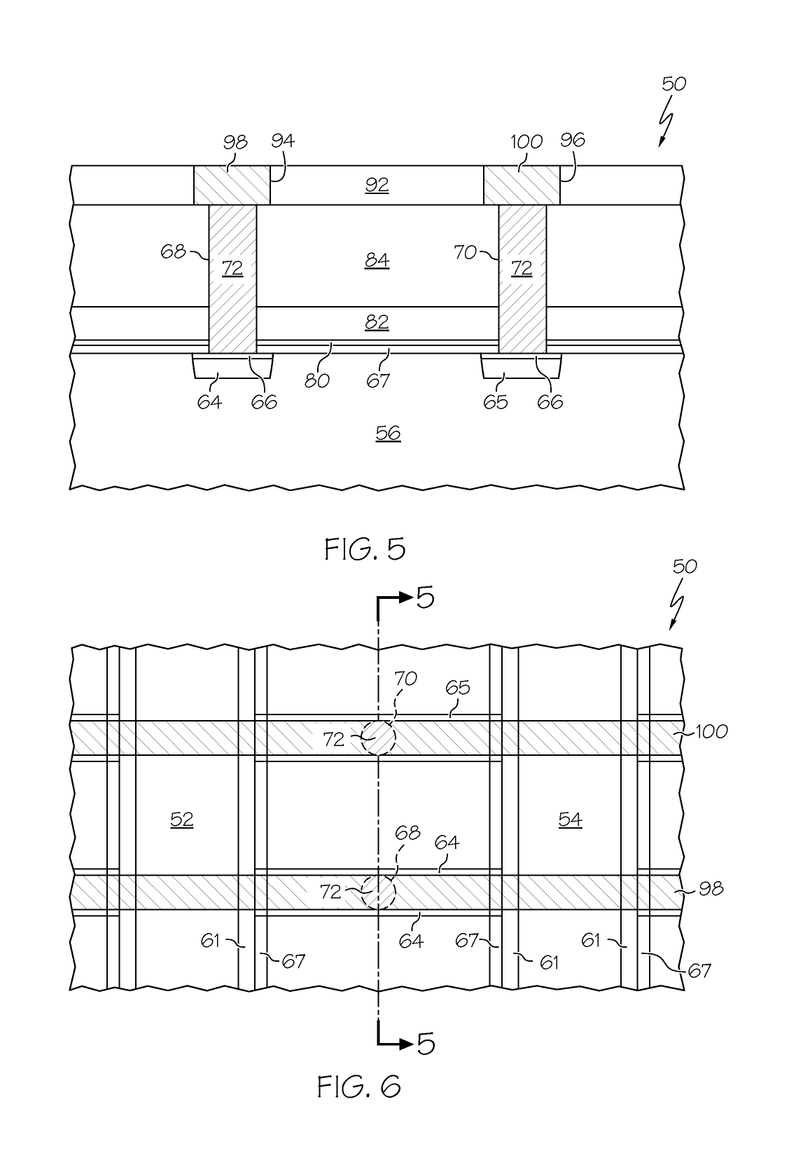

FIG. 5 illustrates, in a cross-sectional view taken parallel to gate structures 52, 54 and through conductive material 72, continuing steps in the fabrication of IC 50 in accordance with one embodiment of the invention. A further layer 92 of interlayer dielectric material is deposited and planarized overlying the planarized surface of insulating layer 84. Layer 92 is patterned and etched using conventional photolithographic patterning and etch techniques to form channels 94 and 96 in the layer in alignment with contact openings 68 and 70, respectively, and with conductive material 72. A layer of copper or other conductive material is deposited or plated in channels 94 and 96 and the excess of such material overlying layer 92 is removed, for example by CMP, to form conductors 98 and 100 by a damascene process. Conductor 98 is electrically coupled through conductive material 72 to source/drain region 64, and conductor 100 is electrically coupled through conductive material 72 to source/drain region 65.

FIG. 6 illustrates, IC 50 in top view. For reference, the cross-section of FIG. 5 is taken along the line 5-5. IC 50 can be, for example but without limitation, a semiconductor memory circuit in which gate structures 52, 54 form word lines and conductors 98, 100 form bit lines. Conductors 98 and 100 contact unassociated active areas, namely source/drain regions 64, 65, and are electrically isolated from each other by ALD layer of insulating material 80 as well as by CVD layers 82 and 84.

Although the methods set forth above have been described with reference to a gate-first process, the same methods can be used to fabricate an integrated circuit by a replacement gate process. In a replacement gate process ALD layer of insulating material 80, SACVD insulating layer 82 and PECVD insulating layer 84 are deposited overlying stress inducing insulating material layer 67, dummy gate structures 52, 54, and source/drain regions 64, 65. Insulating layer 84 is planarized, layer 67 is removed from over the dummy gate structures, the dummy gates are removed and the replacement gates are formed. Thus, although the formation of the final gate structure is different, the formation of the void free ILD layer in the space between the gate structures and overlying and between the source/drain regions is the same as described above.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

What is claimed is:

1. A method for manufacturing an integrated circuit comprising:
forming first and second spaced apart gate structures overlying a semiconductor substrate;
forming first and second spaced apart source/drain regions in the semiconductor substrate between the first and second gate structures;
depositing a first layer of insulating material overlying the first and second gate structures and the first and second source/drain regions by a process of atomic layer deposition;
depositing a second layer of insulating material overlying the first layer by a process of chemical vapor deposition;
etching first and second openings through the second layer and the first layer to expose portions of the first and second source/drain regions, respectively; and
filling the first and second openings with conductive material to form first and second spaced apart contacts in electrical contact with the first and second source/drain regions, respectively, the first and second contacts electrically isolated from each other.

2. The method of claim 1 wherein depositing a first layer comprises depositing a first layer of silicon oxide having a thickness of between about 6 and 10 nm.

3. The method of claim 1 wherein depositing a second layer comprises depositing a layer of oxide having a thickness between about 95 and 105 nm deposited by a process of subatmospheric chemical vapor deposition.

4. The method of claim 3 further comprising:
depositing a third layer of oxide overlying the second layer by a process of plasma enhanced chemical vapor deposition;
planarizing an upper surface of the third layer by chemical mechanical planarization; and
wherein etching first and second openings further comprises etching first and second openings through the third layer.

5. The method of claim 4 further comprising forming first and second spaced apart copper lines by a damascene process overlying the third layer and contacting the first and second contacts, respectively.

6. The method of claim 1 further comprising:
forming sidewall spacers on the first and second gate structures; and
forming a metal silicide on the first and second source/drain regions in self alignment with the sidewall spacers.

7. The method of claim 6 further comprising depositing a layer of stress inducing insulating material overlying the gate structures.

8. A method for fabricating an integrated circuit comprising:
forming first and second spaced apart structures overlying a semiconductor substrate;
depositing a first layer of insulating material overlying the structures by a process of atomic layer deposition;
depositing a second layer of insulating material overlying the first layer; and
forming first and second spaced apart electrically conductive contacts extending through the second layer and the first layer to the semiconductor substrate between the first and second structures.

9. The method of claim 8 further comprising forming first and second regions doped with conductivity determining impurities in the semiconductor substrate between the first and second structures.

10. The method of claim 9 wherein forming first and second regions comprises:
ion implanting conductivity determining ions into the semiconductor substrate in self alignment with the first and second structures; and
forming metal silicide contacts to the first and second regions.

11. The method of claim 8 wherein forming first and second structures comprises:
forming a gate insulator layer;
forming first and second polycrystalline silicon gate electrodes overlying the gate insulator layer;
forming sidewall spacers on the first and second gate electrodes.

12. The method of claim 11 further comprising depositing a layer of stress inducing insulating material overlying the first and second gate electrodes.

13. The method of claim 8 wherein depositing a first layer comprises depositing a layer of silicon oxide having a thickness of 6-10 nm.

14. The method of claim 13 wherein depositing a second layer comprises:
depositing a second layer of silicon oxide by a process of subatmospheric chemical vapor deposition; and
depositing a third layer of silicon oxide overlying the second layer by a process of plasma enhanced chemical vapor deposition.

15. A method for fabricating an integrated circuit comprising:
forming first and second spaced apart gate electrode structures overlying a semiconductor substrate;
forming sidewall spacers on the first and second gate electrode structures;
ion implanting first and second spaced apart source/drain regions between the first and second gate electrode structures;
forming metal silicide contacts on the first and second source/drain regions;
depositing a layer of stress inducing dielectric material overlying the first and second gate electrode structures;
depositing a first layer of oxide overlying the first and second gate electrode structures and first and second source/drain regions by a process of atomic layer deposition;
depositing a second layer of oxide overlying the first layer by a process of chemical vapor deposition;
depositing a third layer of oxide overlying the second layer by a process of plasma enhanced chemical vapor deposition;
planarizing the third layer;
etching first and second spaced apart opening through the third layer, second layer, and first layer to expose portions of the metal silicide contacts; and
filling the first and second openings with conductive material to form first and second spaced apart contacts to the first and second source/drain regions.

16. The method of claim 15 wherein depositing a first layer comprises depositing a layer of silicon oxide having a thickness of about 6-10 nm and wherein depositing a second layer comprises depositing a layer of silicon oxide having a thickness of about 95-105 nm by a process of subatmospheric chemical vapor deposition.

17. The method of claim 16 further comprising forming spaced apart conductive lines overlying the third layer and electrically coupled to the first and second contacts.
